(19) United States
(12) Patent Application Publication
(10) Pub. No.: US 2013/0189838 A1
(43) Pub. Date: Jul. 25, 2013

(54) SEMICONDUCTOR MANUFACTURING APPARATUS AND METHOD OF MANUFACTURING SEMICONDUCTOR DEVICE

(71) Applicants: Makoto HONDA, Yokohama-Shi (JP); Tomonori AOYAMA, Yokohama-Shi (JP)

(72) Inventors: Makoto HONDA, Yokohama-Shi (JP); Tomonori AOYAMA, Yokohama-Shi (JP)

(21) Appl. No.: 13/597,879

(22) Filed: Aug. 29, 2012

(30) Foreign Application Priority Data
Jan. 20, 2012 (JP) 2012-9968
Feb. 6, 2012 (JP) 2012-022999

(51) Int. Cl. H01L 21/44

(52) U.S. Cl. 438/660; 118/723 MW; 257/E21.476

(57) ABSTRACT

According to one embodiment, a semiconductor manufacturing apparatus has a chamber, a microwave generator for generating a microwave, a waveguide for introducing the microwave into the chamber, a stage for mounting a semiconductor substrate, and a cover for covering an outer circumference portion of the stage exposed from the semiconductor substrate. In the semiconductor manufacturing apparatus, the stage is made of a material to be heated by the microwave, and the cover is made of a material through which the microwave penetrates.

### CROSS-REFERENCE TO RELATED APPLICATION

This application is based upon and claims the benefit of priority from prior Japanese Patent Application No. 2012-9968, filed on Jan. 20, 2012, and, prior Japanese Patent Application No. 2012-22999, filed on Feb. 6, 2012, the entire contents of which are incorporated herein by reference.

### FIELD

Embodiments of the present invention relate to a semiconductor manufacturing apparatus and a method of manufacturing a semiconductor device.

### BACKGROUND

In a conventional semiconductor manufacturing apparatus, in particular, in a film forming processing apparatus (for example, a chemical vapor deposition (CVD) apparatus or a physical vapor deposition (PVD) apparatus) that performs a process of forming a metal film and an insulating film on a semiconductor substrate (hereinafter, referred to as a wafer), a wafer is placed on a stage heater or a stage heater having a function of an electrostatic chuck (ESC), and a metal film and an insulating film are formed in a state in which the wafer is heated.

A conventional film forming processing apparatus includes a resistance and a lamp for heating, and a pipe and a groove through which a solvent for cooling flows, and has a configuration that may control a temperature of a chamber side wall, a top board (lid), a pipe (for example, a gas pipe), and the like. In addition, in the conventional film forming processing apparatus, heating a stage by using resistance heating is mainstream.

However, the conventional film forming processing apparatus may not directly heat and cool a shower plate, a cover used to protect a place near a stage from a reactive gas, a cover used to form a non-film forming area in an edge portion of a wafer, a baffle plate used for a stable evacuation, and the like. For this reason, at the time of film forming, a metal film and an insulating film are formed in a shower plate, a covering used to protect a place near a stage from a reactive gas, and a cover used to form a non-film forming area in an edge portion of a wafer. Further, the metal film and the insulating film formed in a place other than the wafer becomes dust through peeling off, entailing a problem of a decrease in yield of a semiconductor device.

Thus, in the conventional film forming processing apparatus, to remove a metal film formed in a place other than the wafer, a reactive gas is periodically introduced into a chamber to remove the metal film through reaction. However, when a cooled place (difference in temperature) is present in the chamber, the reactive product is reattached to be a cause of dust. Further, since a process of removing the metal film is necessary, there is a problem in that productivity is lowered, or a cost of manufacturing the semiconductor device increases.

Furthermore, with miniaturization of the semiconductor device, small sized dust may be a killer (a cause of lowered productivity) and thus, the above-described process for reducing dust is highly important. Accordingly, a manufacturing process or cost may increase. In addition, it is difficult to precisely perform the process, which causes an increase in a manufacturing process.

### BRIEF DESCRIPTION OF THE DRAWINGS

FIG. 1 is a configuration diagram illustrating a semiconductor manufacturing apparatus according to a first embodiment;

FIG. 2 is a configuration diagram illustrating a semiconductor manufacturing apparatus according to a modified example of the first embodiment;

FIG. 3 is a configuration diagram illustrating a semiconductor manufacturing apparatus according to a second embodiment;

FIGS. 4A to 4C are diagrams illustrating a method of manufacturing a semiconductor device according to a third embodiment;

FIGS. 5A to 5C are diagrams illustrating a method of manufacturing a semiconductor device according to a fourth embodiment;

FIGS. 6A and 6B are diagrams illustrating a method of manufacturing a semiconductor device according to a fifth embodiment; and

FIGS. 7A and 7B are diagrams illustrating a method of manufacturing a semiconductor device according to the sixth embodiment.

### DETAILED DESCRIPTION

In one embodiment, a semiconductor manufacturing apparatus includes: a chamber; a microwave generator for generating a microwave; a waveguide for introducing the microwave into the chamber; a stage for mounting a semiconductor substrate; and a cover for covering an outer circumference portion of the stage exposed from the semiconductor substrate. In semiconductor manufacturing apparatus, the stage is made of a material to be heated by the microwave, and the cover is made of a material through which the microwave penetrates.

Hereinafter, embodiments will be described with reference to drawings. However, the invention is not limited to the embodiments. Here, common reference numerals are assigned to common portions over the entire drawings, and repeated description thereof will not be provided. Further, the drawings are schematic diagrams for describing the invention and promoting understanding thereof, and there is a place having different shape, size, proportion, and the like from an actual device, which may be appropriately changed by taking descriptions below and a known technology into consideration.

### First Embodiment

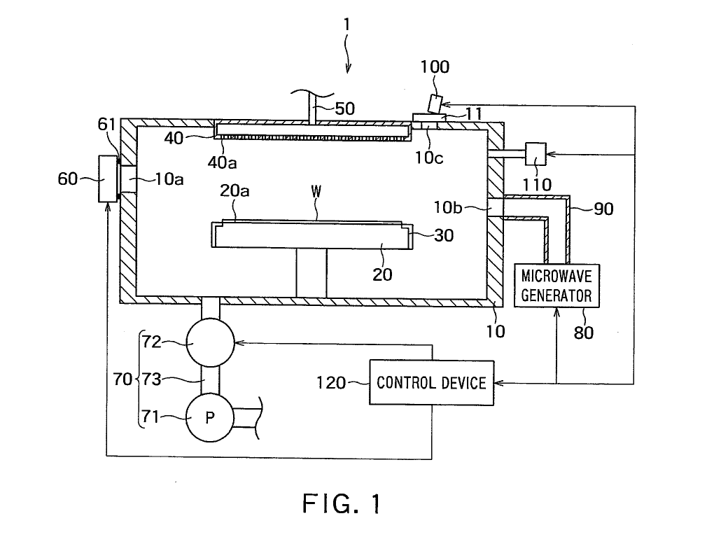

FIG. 1 is a configuration diagram illustrating a semiconductor manufacturing apparatus 1 according to a first embodiment (hereinafter, referred to as a semiconductor manufacturing apparatus 1). The semiconductor manufacturing apparatus 1 includes a chamber 10, a stage 20, a covering 30, a shower plate 40, a gas supply unit 50, a gate valve 60, a vacuuming unit 70, a microwave generator 80, a waveguide 90, a thermometer 100, a pressure gauge 110, and a control device 120.

The semiconductor manufacturing apparatus 1 is a W-CVD device that forms a tungsten (W) film on a semiconductor substrate W (hereinafter, referred to as a wafer W). The semiconductor manufacturing apparatus 1 supplies, for example, tungsten hexafluoride (WF₆) gas (raw material gas) and hydrogen (H₂) gas (reducing gas) into the chamber 10 to form the tungsten film on the wafer W.

Further, in the semiconductor manufacturing apparatus 1, the wafer W is heated using a microwave. In the chamber 10, a place where the temperature is desired to be increased is made of a material that absorbs or reflects a microwave (for example, a polymer material including a dipole and a magnetic material (for example, nickel (Ni))), or a non-magnetic metal material having a low resistance (for example, aluminum (Al)), and a place where the temperature is not desired to be increased is made of a material through which a microwave penetrates (for example, quartz). Hereinafter, each element included in the semiconductor manufacturing apparatus 1 is described.

The chamber 10 is a container used to perform a film forming process, and is constructed to maintain airtightness. The stage 20, the covering 30, and the shower plate 40 are accommodated in the chamber 10. The chamber 10 includes a first opening 10a used to carry in and out the wafer W, a second opening 10b used to introduce a microwave, and a third opening 10c used to measure the temperature. Here, the second opening 10b is formed in a position between the shower plate 40 and the stage 20. Further, a window 11 made of quartz and the like is provided in the third opening 10c.

The stage 20 holds the wafer W on an upper surface 20a. The stage 20 is made of the above-mentioned material that absorbs a microwave (for example, a polymer material including a dipole, a magnetic material, a non-magnetic metal material having a low resistance, and the like). By forming the stage 20 using a material that may be heated through absorption of a microwave, the wafer W may be heated from a rear surface. As a result, the wafer W may be efficiently heated. Here, when a microwave is radiated from a rear surface, the stage 20 may be made of a material through which a microwave penetrates.

Further, the stage 20 may not be heated, and only the wafer W may be heated. In this case, the stage 20 is made of a material through which a microwave penetrates.

The covering 30 is a cover used to protect a place near the stage 20 from a reactive gas, or used to inhibit deposition of a film in an edge, a bevel, a rear surface, and the like of the wafer W, as possible. The covering 30 is made of quartz through which a microwave penetrates, and covers an outer circumference portion of the stage 20 exposed from the wafer W that is held on the upper surface 20a of the stage 20.

When the covering 30 is made of quartz, it is possible to lower the temperature of the covering 30. Thus, a tungsten film is difficult to be formed on the covering 30. As a result, it is possible to effectively inhibit a decrease in yield of a semiconductor chip due to peeling off and the like of a metal film formed in a place other than the wafer W.

Further, a reactive gas or a raw material gas of a CVD may be inhibited from adhering to the covering 30 by increasing the temperature of the covering 30 depending on a reactive gas or a raw material gas of a CVD to be used. In this case, the covering 30 may be made of a material that absorbs a microwave.

Moreover, a dry-cleaning for removing a tungsten film deposited inside the chamber 10 may be unnecessary, or the number of times of dry-cleaning may be significantly reduced. Thus, productivity of the semiconductor chip may be enhanced. Further, it is possible to suppress an increase in cost of manufacturing a semiconductor chip. Furthermore, it is possible to reduce deterioration of the semiconductor manufacturing apparatus 1 due to a dry-cleaning, for example, corrosion in the chamber 10, deterioration of an O-ring, and the like.

The shower plate 40 is a circular plate in which a plurality of through-holes 40a is formed, and diffuses and introduces, into the chamber 10, a raw material gas (WF₆) or a reducing gas (H₂) supplied from the gas supply unit 50. Here, the shower plate 40 is made of a non-magnetic material having a low resistance (for example, aluminum) to inhibit adsorption of the raw material gas (WF₆).

An inner diameter of the through-holes 40a formed in the shower plate 40 may be equal to or less than a half wavelength of a microwave, which may prevent a wraparound of a microwave to a side of the gas supply unit 50.

The gas supply unit 50 is connected to a gas supply source (not illustrated), and supplies various types of gas used to manufacture a semiconductor chip into the chamber 10. In this embodiment, a first system that supplies a raw material gas (WF₆) and a reducing gas (H₂) used to form a tungsten film, and a second system that supplies a fluorine-based gas (for example, CF₄ gas, C₂F₆ gas, SF₆ gas, and NF₃ gas), a chlorine-based gas (Cl₂ gas and BCl₄ gas), and a carrier gas (for example, Ar gas and N₂ gas) used for a dry-cleaning are provided.

The first and second systems include a mass flow controller (MFC) that controls a gas mass flow for each type of gas, and a valve that supplies and shuts off a gas.

The gate valve 60 opens and closes the first opening 10a of the chamber 10. The gate valve 60 includes an O-Ring 61 on a surface opposed to a side wall of the chamber 10 to maintain airtightness of the chamber 10.

The vacuuming unit 70 includes a vacuuming pump 71, a throttle valve 72, and a vacuum plumbing 73 in which one end side is connected to the chamber 10 and the other end side is connected to the vacuuming pump 71. The throttle valve 72 is disposed between the chamber 10 and the vacuuming pump 71, and controls a pressure in the chamber 10 by changing a conductance of the vacuum plumbing 73. Here, an exhaust side of the vacuuming pump 71 is connected to an elimination device (not illustrated).

The microwave generator 80 generates a microwave having a frequency of 2.45 GHz to 25 GHz. Further, when a microwave generator capable of changing a generation frequency is used, a non-magnetic material having a low resistance may be heated by induction heating. Two microwave generators 80 having different generation frequency bands may be provided. By changing a frequency of a microwave, it is possible to heat any one of a polymer material including a dipole, a magnetic material (for example, nickel (Ni)), or a non-magnetic metal material having a low resistance (for example, aluminum (Al)).

The waveguide 90 is connected to the microwave generator 80 through one end side thereof, and is connected to the second opening 10b of the chamber 10 through the other end side thereof. The waveguide 90 introduces a microwave generated in the microwave generator 80 into the chamber 10 from the opening 10b.

The semiconductor manufacturing apparatus 1 may be provided with the thermometer 100. The thermometer 100 is, for example, a non-contact thermometer (for example, a radiation thermometer), and measures a temperature of the wafer W placed on the upper surface 20a of the stage 20 from the window 11 provided in the third opening 10c of the chamber 10. The thermometer 100 outputs a measured temperature to the control device 120. Here, the thermometer 100 is not limited to the non-contact thermometer, and various structures of thermometer may be used.

The pressure gauge 110 measures a pressure in the chamber 10. The pressure gauge 110 outputs a measured pressure to the control device 120.

The control device 120 controls the entire semiconductor manufacturing apparatus 1. The a control device 120 controls, for example, opening and closing of the gate valve 60, and an operation of the MFC and the valve included in the gas supply unit 50. Further, the control device 120 controls an opening degree of the throttle valve 72 based on a pressure output from the pressure gauge 110. Furthermore, the control device 120 controls a power (wattage) of the microwave generator 80 such that a temperature output from the thermometer 100 is, for example, 400° C.

As described above, semiconductor manufacturing apparatus 1 heats the wafer W by a microwave. In this instance, in the chamber 10, a place (for example, the stage 20) where the temperature is desired to be increased is made of a material that absorbs a microwave (for example, a polymer material including a dipole, a magnetic material, or a non-magnetic metal material having a low resistance), and a place (for example, the covering 30) where the temperature is not desired to be increased is made of a material through which a microwave penetrates (for example, quartz).

For this reason, a tungsten film is difficult to be formed on the covering 30. As a result, it is possible to effectively inhibit a decrease in yield of a semiconductor chip due to peeling off and the like of a metal film formed in a place other than the wafer W. Further, a dry-cleaning for removing a tungsten film deposited inside the chamber 10 may be unnecessary, or the number of times of dry-cleaning may be significantly reduced. Thus, productivity of the semiconductor chip may be enhanced. Further, it is possible to suppress an increase in cost of manufacturing a semiconductor chip. Furthermore, it is possible to reduce deterioration of the semiconductor manufacturing apparatus 1 due to a dry-cleaning, for example, corrosion in the chamber 10, deterioration of an O-ring, and the like. Further, electrical energy amount used for heating may be reduced when compared to heating by a resistance heating.

Here, in the above-described invention, the semiconductor manufacturing apparatus 1 that forms a tungsten (W) film has been described. However, the invention may be applied to a CVD device that forms a metal film (for example, an Al film, a Ti film, a TiN film, and a Si film) or an insulating film (for example, a SiO₂ film) in addition to the tungsten film.

### Modified Example of First Embodiment

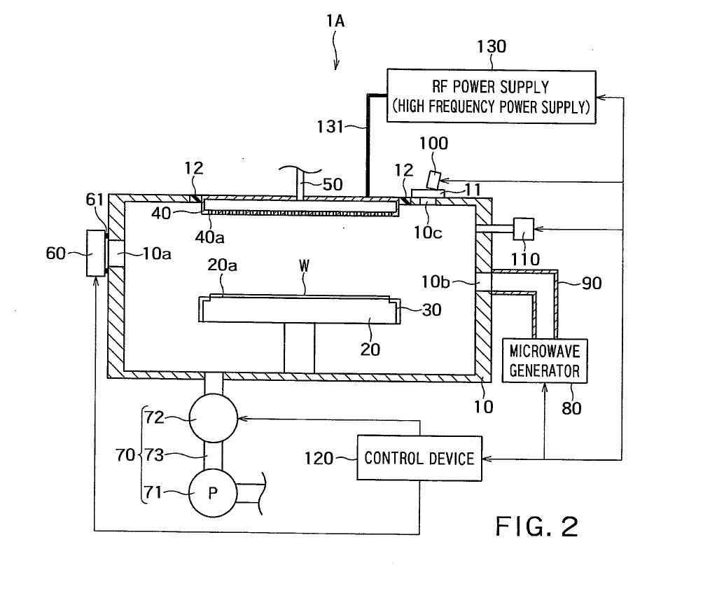

FIG. 2 is a configuration diagram illustrating a semiconductor manufacturing apparatus 1A according to a modified example of the first embodiment (hereinafter, referred to as a semiconductor manufacturing apparatus 1A). The semiconductor manufacturing apparatus 1A further includes a radio frequency (RF) power source (high-frequency power source) 130 that generates a high-frequency wave (for example, 13.56 MHz), an RF cable 131 that connects the shower plate 40 with the RF power source 130, and an insulator 12 that puts the shower plate 40 in a state (floating state) of being electrically insulated from the chamber 10, and is a plasma enhanced-CVD (PE-CVD) apparatus that allows a gas supplied into the chamber 10 to be plasma. Here, the same reference numeral is assigned to the same element as that described with reference to FIG. 1, and repeated description is not provided.

When a gas supplied into the chamber 10 becomes plasma as in this embodiment, a region including plasma (hereinafter, referred to as a plasma region) and a region including a microwave (hereinafter, referred to as a microwave region) need to be separated from each other. Thus, in the semiconductor manufacturing apparatus 1A, an inner diameter of the plurality of through-holes 40a formed in the shower plate 40 is equal to or less than a half wavelength of a microwave.

When an inner diameter of the plurality of through-holes 40a formed in the shower plate 40 is equal to or less than a half wavelength of a microwave, a wraparound of a microwave into the shower plate 40 is reduced. An upstream of the shower plate 40 is set to the plasma region, and the downstream of the shower plate 40 is set to the microwave region. Other effects are similar to those of the semiconductor manufacturing apparatus 1 according to the first embodiment.

### Second Embodiment

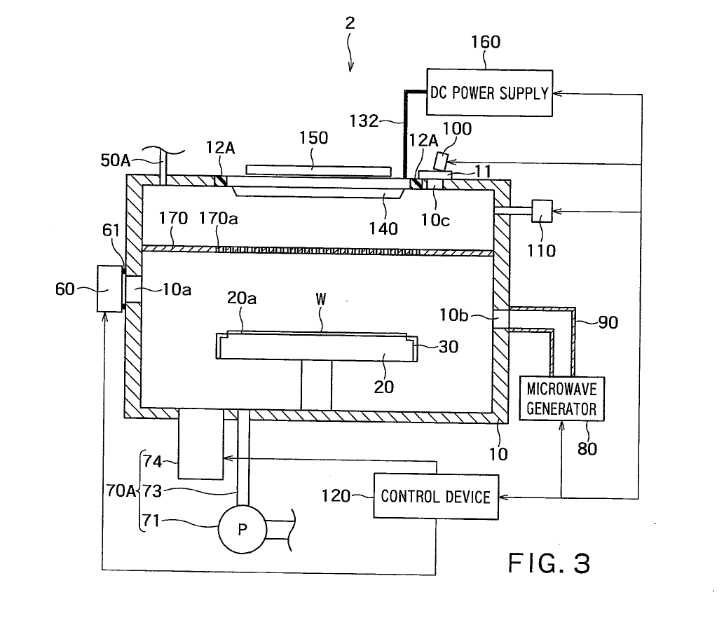

FIG. 3 is a configuration diagram illustrating a semiconductor manufacturing apparatus 2 according to a second embodiment (hereinafter, simply referred to as a semiconductor manufacturing apparatus 2). The semiconductor manufacturing apparatus 2 is a PVD apparatus that forms a metal film on a wafer W. Hereinafter, a configuration of the semiconductor manufacturing apparatus 2 will be described with reference to FIG. 3. The same reference numeral refers to the same element as that described with reference to FIGS. 1 and 2, and repeated description is not provided.

The semiconductor manufacturing apparatus 2 includes a chamber 10, an insulator 12A, a stage 20, a covering 30, a gas supply unit 50A, a gate valve 60, a vacuuming unit 70A, a microwave generator 80, a waveguide 90, a thermometer 100, a pressure gauge 110, a control device 120, a direct current (DC) cable 132, a target 140, a magnet 150, a DC power source 160, and a collimator 170.

The insulator 12A is disposed between the chamber 10 and the target 140, and is an insulator that puts the target 140 in a state (floating state) of being electrically insulated from the chamber 10. The DC cable 132 connects the target 140 with the DC power source 160.

The gas supply unit 50A is connected to a gas supply source (not illustrated), and supplies various types of gas used to manufacture a semiconductor chip into the chamber 10. In this embodiment, the gas supply unit 50A supplies, for example, Ar gas into the chamber 10.

The vacuuming unit 70A includes a vacuuming pump 71, a cryopump 74, and a vacuum plumbing 73 in which one end side is connected to the chamber 10 and the other end side is connected to the vacuuming pump 71. The semiconductor manufacturing apparatus 2 needs a high degree of vacuum to perform a film forming by a PVD. Thus, the semiconductor manufacturing apparatus 2 is roughly deflated to a low degree of vacuum through the vacuuming pump 71, and then vacuumed to a high degree of vacuum through the cryopump 74.

The target 140 is disposed to face an upper surface 20a of the stage 20. The target 140 is made of metal such as Al, Ti, and the like. The magnet 150 is disposed on a rear surface side of the target 140, and enhances a degree of density of plasma formed on the target 140 and an in-plane uniformity of a metal film formed on the wafer W.

The DC power source 160 applies a negative voltage to the target 140, and forms plasma of Ar ions in the vicinity of a surface of the target 140. The Ar ions collide with a surface of a negatively-biased target 140, and “sputter” the target 140. An atom or a molecule emitted from the target 140 is deposited on the wafer W and thus, a metal film is formed.

The collimator 170 is disposed between the target 140 and the stage 20. A plurality of through-holes (slits) 170a is formed in the collimator 170, and only an atom or molecule having a high straightness among atoms and molecules flown from the target 140 passes through the through-holes 170a.

Further, an inner diameter of the through-holes 170a formed in the collimator 170 is equal to or less than a half wavelength of a microwave, preventing a wraparound of a microwave to a side of the target 140. A function of separating a plasma region formed on the target 140 and a microwave region including a microwave is included. Here, in the semiconductor manufacturing apparatus 2, a microwave is introduced into a position between the collimator 170 and the stage 20.

As described above, in the semiconductor manufacturing apparatus 2, the collimator 170 is provided between the target 140 and the stage 20, and an inner diameter of the plurality of through-holes 170a formed in the collimator 170 is equal to or less than a half wavelength of a microwave, thereby preventing a wraparound of a microwave to a side of the target 140. As such, it is possible to set an upstream of the collimator 170 to a plasma region, and a downstream of the collimator 170 to a microwave region. Other effects are similar to those of the semiconductor manufacturing apparatus 1 according to the first embodiment.

Since a quality of a film to be formed varies depending on a forming temperature, a film stress changes depending on a forming temperature. Thus, an amount of dust and the like varies depending on a forming temperature. That is, whether heating suppresses an amount of dust and the like, or whether not heating suppresses an amount of dust and the like differs depending on a type of film to be formed. Thus, in a case of this embodiment, it is preferable to select whether to form a component included in the semiconductor manufacturing apparatus using a material that absorbs a microwave or using a material through which a microwave penetrates based on a type of film to be formed. Examples of a target of selecting whether to use a material that absorbs a microwave or use a material through which a microwave penetrates include an adhesion preventing plate, a stage, a covering, a collimator, and the like.

Further, a PVD apparatus that forms a metal film is described in the first and second embodiments. However, when an RF power source (high-frequency power source) is used instead of a DC power source, it is possible to form an insulating film on the wafer W.

### Third Embodiment

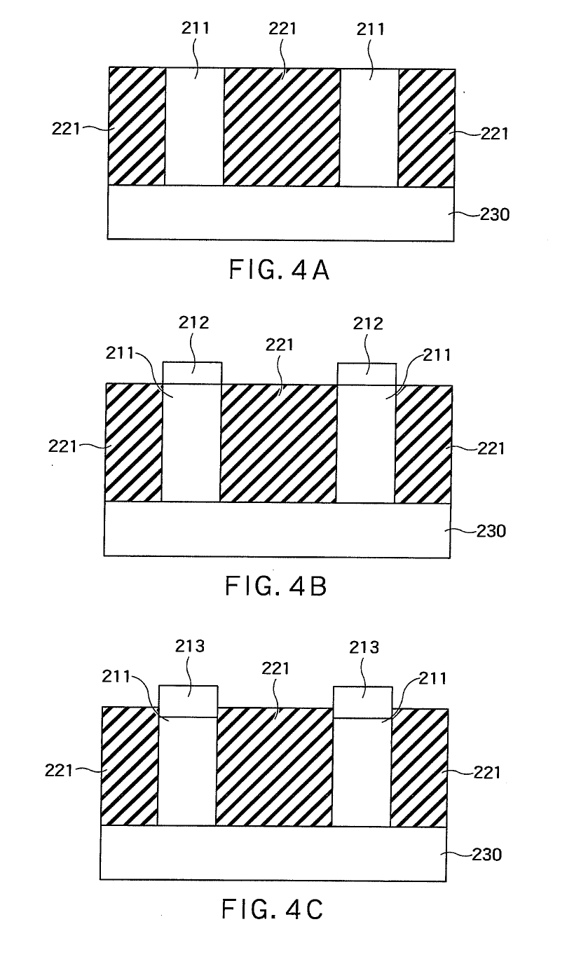

A manufacturing method according to this embodiment will be described with reference to FIGS. 4A to 4C. The diagrams are cross-sectional views illustrating each process in the manufacturing method according to this embodiment. Here, a process of forming a conductive film (third conductive film) 213 formed from a nickel silicide film on a conductive film (first conductive film) 211 provided on a silicon wafer (semiconductor substrate) 230 is described as an example. However, the invention is not limited to the manufacturing method.

First, as illustrated in FIG. 4A, the silicon wafer 230 on which a desired pattern is formed using the conductive film 211 and an insulating film (first insulating film) 221 is prepared. The conductive film 211 forming the pattern on the silicon wafer 230 is, for example, a silicon film. However, the invention is not limited thereto, and a metal film, a half metal film, or a metal alloy film may be used. Further, the insulating film 221 may be formed from a silicon oxide film, a silicon nitride film, an aluminum oxide film, an aluminum nitride film, a boron nitride film, a silicon oxynitride film, a silicon carbide film, an organic material film, a polymer material film, or a combination thereof. Hereinafter, description is made on the assumption that the conductive film 211 is formed from, for example, a silicon film.

Subsequently, a microwave of 2.45 GHz to 25 GHz is radiated to the silicon wafer 230 on which a desired pattern is formed using the silicon film 211 and the insulating film 221. A radiation condition of the microwave is set such that a surface temperature of the silicon film 211 is, for example, in a range of 100 to 550° C. Specifically, a radiation power of the microwave is 10 W/cm² to 10 kW/cm², and a radiation time is 30 seconds to 30 minutes. In this instance, since an absorption rate of a microwave varies depending on a composition, a surface temperature of the silicon film 211 is higher than a surface temperature of the insulating film 221 by 50° C. or more. Here, a surface temperature of the silicon film 211 and the insulating film 221 is measured using a non-contact temperature measuring instrument such as a pyrometer.

Then, as illustrated in FIG. 4B, while maintaining a state in which a surface temperature of the silicon film 211 is higher than a surface temperature of the insulating film 221 by 50° C. or more by radiating a microwave, a conductive film 212 (second conductive film) is deposited on the silicon film 211. Since a surface temperature of the silicon film 211 is higher than a surface temperature of the insulating film 221 by 50° C. or more, the conductive film 212 is selectively deposited on the silicon film 211. Thus, since the conductive film 212 may be deposited on a necessary place, it is possible to suppress a cost of material for the conductive film 212. In a subsequent process, a process of forming the conductive film 212 in a desired shape such as a reactive ion etching (RIE), a chemical mechanical polishing (CMP) may not be performed, and a cost of manufacturing may be suppressed. Further, since a temperature of a surface of the silicon film 211 on which the conductive film 212 is deposited is higher than a temperature of a portion other than the surface of the silicon film 211 such as the insulating film 221 or a lower layer interconnection (not illustrated), it is possible to minimize a thermal damage to a portion other than the silicon film 211. Furthermore, in this instance, by radiating a microwave, it is possible to form the conductive film 212 including few impurities. The reason thereof will be described later.

Further, the conductive film 212 is formed from, for example, a nickel film. However, the invention is not limited thereto, and it is possible to use a metal film, a half metal film, or a metal alloy film containing at least one selected from Al, Si, Ti, Ni, Co, Cu, Nb, Mo, Ru, Pd, Ag, Sn, Mn, La, Hf, Ta, and W. Hereinafter, description is made on the assumption that the conductive film 212 is formed from a nickel film.

Subsequently, as illustrated in FIG. 4C, in the same chamber as a chamber (semiconductor manufacturing device) hitherto used, in other words, without an ejection from the chamber, a microwave is radiated on the nickel film 212 deposited on the silicon film 211. Or, for example, a heat treatment of 200° C. or more is performed using a rapid thermal annealing (RTA) in another chamber. Through this, the silicon film 211 reacts with the nickel film 212, thereby forming a conductive film 213 formed from a nickel silicide (NiSix) film. In this instance, since the nickel film 212 is scarcely deposited on the insulating film 221, the nickel silicide film 213 is not formed on the insulating film 221. Thereafter, a wet process may be performed. The nickel silicide film 213 is formed to have a thickness of several nanometers (nm) to several hundred nm depending on usage and the like. Here, a composition of the third conductive film 213 to be formed varies depending on a composition of the conductive film 211 and the conductive film 212. Since the nickel silicide film 213 may be formed using the nickel film 212 selectively deposited on the silicon film 211, it is easy to control a shape, a thickness, and a composition of the nickel silicide film 213. Specifically, when it is difficult to selectively deposit the nickel film 212, the nickel film 212 is deposited on the semiconductor substrate 230 and on the insulating film 221 adjacent to the silicon film 211. The nickel film 212 present in a region (on the insulating film 221 or on a material through which a microwave penetrates) adjacent to the silicon film 211 serves as a supply source of nickel element together with the nickel film 212 deposited on the silicon film 211 when forming the nickel silicide film 213 and thus, it is not easy to obtain a desired shape, thickness, and composition of the nickel silicide film 213 to be ultimately formed. However, in this embodiment, the nickel film 212 selectively deposited on the silicon film 211 serves as a supply source of nickel element and thus, it is easy to control a shape, thickness, and composition of the nickel silicide film 213 as desired. Accordingly, since the nickel silicide film 213 may be formed as desired, a defect such as a leak may be significantly decreased.

In this embodiment, since a microwave is radiated to the silicon wafer 230 on which the conductive film 211 and the insulating film 221 are formed, and an absorption rate of a microwave varies depending on a composition, a surface temperature of the conductive film 211 may be higher than a surface temperature of the insulating film 221 by 50° C. or more. When the conductive film 212 is deposited by a CVD method while maintaining the above-described state, the conductive film 212 may be selectively deposited on a place having a high surface temperature, that is, on the conductive film 211. Accordingly, since a temperature of a place where the conductive film 212 is deposited is higher than a temperature of a portion other than the place, it is possible to minimize a thermal damage to the portion other than the place where the silicon film 212 is deposited. Furthermore, it is possible to avoid a defect such as a leak being generated in a formed semiconductor device. Further, since a cost of material for the conductive film 212 may be suppressed, and a process of forming the conductive film 212 in a desired shape such as an RIE may not be performed thereafter, it is possible to suppress a cost of manufacturing.

In addition, when the conductive film 212 is deposited by a CVD method, a raw material gas may contain a lot of impurities such as oxygen, carbon, fluorine, chlorine, nitrogen, and water. In this embodiment, when a microwave is radiated when the conductive film 212 is deposited, the impurities adhering onto the conductive film 211 are activated by the microwave, or a reducing gas contained in a raw material gas is activated by the microwave and reacts with the impurities, or a metallic element contained in a raw material gas is activated by the microwave, functions as a catalyst, reacts with the impurities, and evaporates the impurities. Through this, the impurities are not deposited on the conductive film 211. According to this embodiment, impurities contained in the conductive film 212 may be reduced when compared to a case in which the conductive film 212 is deposited by a CVD method while heating is performed by an RTA method.

Further, according to this embodiment, as illustrated in the foregoing, since the conductive film 213 may be formed using the conductive film 212 selectively deposited on the conductive film 211, it is easy to control a shape, a thickness, and a composition of the conductive film 213. In particular, when a metal film, a half metal film, or a metal alloy film containing Ni or Co is used as the conductive film 212, the control is more facilitated since these elements are easily diffused and reactive to a temperature. Further, since a temperature of a place where the conductive film 212 is deposited is high, it is possible to avoid a metal element contained in the conductive film 212 being excessively diffused to a portion other than the place where the conductive film 212 is deposited.

Here, with regard to forming of the conductive film 213, while maintaining a state in which a surface temperature of the conductive film 211 is higher than a surface temperature of the insulating film 221 by 50° C. or more by radiating a microwave in the same condition as the above-described condition, the conductive film 213 may be directly deposited on the conductive film 211 by using a CVD method. For example, by a CVD method using a mixed gas in which a gas containing Ni is mixed with a gas containing silicon such as Si₂H₆, the conductive film 213 formed from a nickel silicide film may be directly deposited on the conductive film 211. In the modified example of the third embodiment, a composition of the conductive film 213 may be easily controlled when compared to the third embodiment.

### Fourth Embodiment

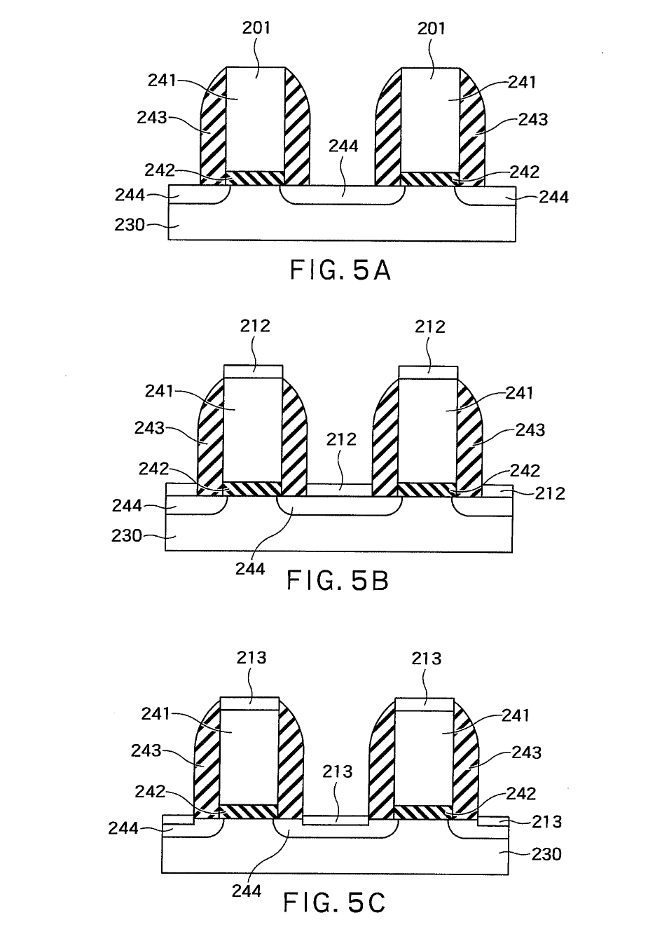

A manufacturing method according to this embodiment will be described with reference to FIGS. 5A to 5C. The diagrams are cross-sectional views illustrating each process in the manufacturing method according to this embodiment, and in particular, correspond to cross-sectional views along a channel width direction of a Metal Oxide Semiconductor Held Effect Transistor (MOSFET) (semiconductor device) 201. Here, a process of forming a conductive film (third conductive film) 213 formed from a nickel silicide film on a gate electrode 241 of the MOSFET 201 and on a source/drain region 244 will be described as an example. However, the invention is not limited to this method of manufacturing a semiconductor device. Further, in description of this embodiment below, the same reference numeral as that of the third embodiment is assigned to a portion having the same configuration and function as that of the third embodiment, and description thereof will not be provided.

First, a plurality of MOSFETs 201 are formed on a silicon wafer (semiconductor substrate) 230 illustrated in FIG. 5A using a known method. The MOSFETs 201 include, for example, the gate electrode 241 formed on the silicon wafer 230, a gate insulating film 242 formed under the gate electrode 241, a gate side wall film 243 that covers a side wall of a layer stack including the gate insulating film 242 and the gate electrode 241, and a source/drain region 244 formed in the vicinity of a surface of the silicon wafer 230 interposing the MOSFET 201 therebetween. The gate electrode 241 is formed from, for example, a polysilicon film. However, the invention is not limited thereto, and a metal film, a half metal film, or a metal alloy film may be used. Further, the gate side wall film 243 is formed from an insulating film, and may be formed from, for example, a silicon oxide film, a silicon nitride film, an aluminum oxide film, an aluminum nitride film, a boron nitride film, a silicon oxynitride film, a silicon carbide film, an organic material film, a polymer material film, or a combination thereof. Hereinafter, description is made on the assumption that the gate electrode 241 is formed from a polysilicon film.

Subsequently, a microwave of 2.45 GHz to 25 GHz is radiated to the silicon wafer 230 on which the plurality of MOSFETs 201 are formed. A radiation condition of the microwave is set similarly to the third embodiment such that a surface temperature of the gate electrode 241 and the source/drain region 244 is, for example, in a range of 100 to 550° C. In this instance, since an absorption rate of a microwave varies depending on a composition, the surface temperature of the gate electrode 241 and the source/drain region 244 is higher than a surface temperature of the gate side wall film 243 by 50° C. or more.

Then, as illustrated in FIG. 5B, similarly to the third embodiment, while maintaining a state in which the surface temperature of the gate electrode 241 and the source/drain region 244 is higher than the surface temperature of the gate side wall film 243 by 50° C. or more by radiating a microwave, a conductive film 212 (second conductive film) is deposited on the gate electrode 241 and the source/drain region 244 by using a CVD method. Since the surface temperature of the gate electrode 241 and the source/drain region 244 is higher than the surface temperature of the gate side wall film 243 by 50° C. or more, the conductive film 212 is selectively deposited on the gate electrode 241 and the source/drain region 244. Specifically, the conductive film 212 is formed from, for example, a nickel film. However, the invention is not limited thereto, and it is possible to use a metal film, a half metal film, or a metal alloy film containing at least one selected from Al, Si, Ti, Ni, Co, Cu, Nb, Mo, Ru, Pd, Ag, Sn, Mn, La, Hf, Ta, and W. Hereinafter, description is made on the assumption that the conductive film 212 is formed from a nickel film. In this instance, as described in the foregoing, by radiating a microwave, it is possible to deposit a nickel film 212 including few impurities.

Subsequently, as illustrated in FIG. 5C, similarly to the third embodiment, a heat treatment of 200° C. or more is performed on the nickel film 212, and the gate electrode 241, the source/drain region 244, and the nickel film 212 react together, thereby forming a conductive film 213 formed from a nickel silicide film.

In this embodiment, similarly to the third embodiment, by radiating a microwave to the silicon wafer 230 on which the plurality of MOSFETs 201 are formed, the surface temperature of the gate electrode 241 and the source/drain region 244 may be higher than the surface temperature of the gate side wall film 243 by 50° C. or more. When the conductive film 212 is deposited by a CVD method while maintaining the above-described state, the conductive film 212 may be selectively deposited on the gate electrode 241 and the source/drain region 244. Accordingly, since a temperature of a place where the conductive film 212 is deposited is higher than a temperature of a portion other than the place, it is possible to minimize a thermal damage to the portion other than the place where the conductive film 212 is deposited. Furthermore, it is possible to suppress a cost of material for the conductive film 212 and a cost of manufacturing.

Further, in this embodiment, similarly to the third embodiment, since a microwave is radiated when the conductive film 212 is deposited by a CVD method, it is possible to reduce impurities in the conductive film 212 when compared to a case in which the conductive film 212 is deposited by a CVD method while heating is performed using an RTA and the like.

Further, according to this embodiment, as described in the foregoing, since the conductive film 213 may be formed using the conductive film 212 selectively deposited on the conductive film 211, a shape, a thickness, and a composition of the conductive film 213 may be easily controlled. Furthermore, a temperature of a place where the conductive film 212 is deposited may be higher than a temperature of a portion other than the place and thus, it is possible to avoid a metal element contained in the conductive film 212 being excessively diffused to a portion other than the place where the conductive film 212 is deposited. Accordingly, for example, it is easy to thinly form the conductive film 213 that is formed on the source/drain region 244.

Here, in this embodiment, with regard to forming of the conductive film 213, similarly to the modified example of the third embodiment, while radiating a microwave, the conductive film 213 may be directly deposited using a CVD method.

### Fifth Embodiment

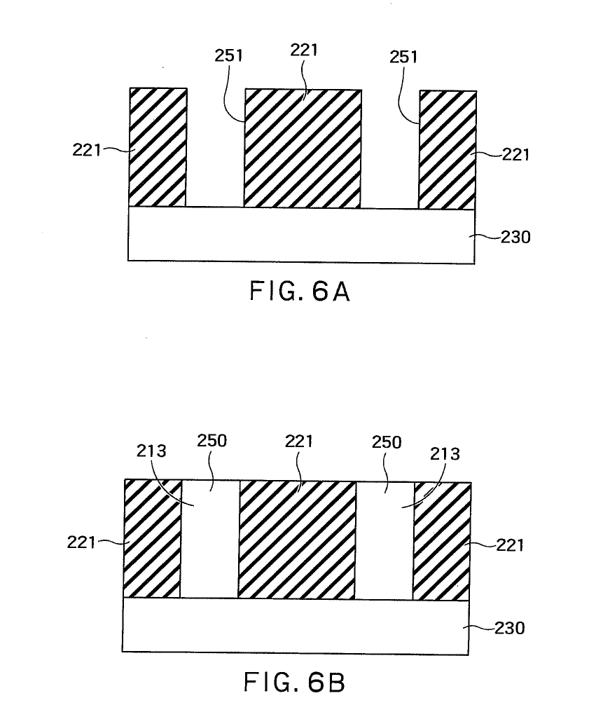

A manufacturing method according to this embodiment will be described with reference to FIGS. 6A and 6B. FIGS. 6A and 6B are cross-sectional views illustrating each process in the manufacturing method according to this embodiment. Here, a process of forming a plurality of interconnections 250 having a damascene structure on a silicon wafer (semiconductor substrate) 230 is described as an example. However, the invention is not limited thereto. Further, in description of this embodiment below, the same reference numeral as that of the third and fourth embodiments is assigned to a portion having the same configuration and function as that of the third and fourth embodiments, and description thereof will not be provided.

First, as illustrated in FIG. 6A, using a known method, an insulating film (first insulating film) 221 is formed on the silicon wafer 230, and a plurality of grooves 251 having a desired shape and size are formed in the insulating film 221. The grooves 251 penetrate into the insulating film 221, and a surface of the silicon wafer 230 is exposed in a bottom thereof. Specifically, the insulating film 221 may be formed from a silicon oxide film, a silicon nitride film, an aluminum oxide film, an aluminum nitride film, a boron nitride film, a silicon oxynitride film, a silicon carbide film, an organic material film, a polymer material film, or a combination thereof.

Here, description is made on the assumption that the grooves 251 are formed, a hole (opening portion) may be formed instead of a groove.

Subsequently, similarly to the third embodiment, a microwave of 2.45 GHz to 25 GHz is radiated to the silicon wafer 230 on which the insulating film 221 including the plurality of grooves 251 is provided. A radiation condition of the microwave is set such that a surface temperature of the silicon wafer 230 exposed in the bottom of the grooves 251 is, for example, in a range of 100 to 550° C. In this instance, since an absorption rate of a microwave varies depending on a composition, the surface temperature of the silicon wafer 230 exposed in the bottom of the grooves 251 is higher than an upper surface temperature of the insulating film 221 and a temperature of a side wall of the grooves 251 formed from the insulating film 221 by 50° C. or more.

As illustrated in FIG. 6B, similarly to the third embodiment, while maintain a state in which the surface temperature of the silicon wafer 230 exposed in the bottom of the grooves 251 is higher than the upper surface temperature of the insulating film 221 and a surface temperature of the side wall of the grooves 251 formed from the insulating film 221 by 50° C. or more by radiating a microwave, a conductive film 213 is deposited as a material for interconnection in the grooves 251 using a CVD method. For example, a nickel silicide film 213 is deposited by a CVD method using a mixed gas in which a gas containing Ni is mixed with a gas containing silicon such as Si₂H₆. Through the above-described formation, similarly to the third embodiment, the conductive film 213 may be selectively deposited on the silicon wafer 230, exposed in the bottom of the grooves 251, having a high temperature. Specifically, since the surface temperature of the side wall of the grooves 251 is low, the conductive film 213 is not deposited on the side wall of the grooves 251, and the conductive film 213 is selectively deposited on the silicon wafer 230, exposed in the bottom of the grooves 251, having a high surface temperature. Accordingly, since the grooves 251 are successively filled with the conductive film 213 from the bottom thereof, it is possible to prevent a void from being generated in the conductive film 213 in the grooves 251. Further, a gas used to deposit the conductive film 213 is, for example, a gas containing at least one selected from Al, Si, Ti, Ni, Co, Cu, Nb, Mo, Ru, Pd, Ag, Sn, Mn, La, Hf, Ta, and W. Accordingly, the formed conductive film 213 is, for example, a metal film or a metal alloy film containing at least one selected from Al, Si, Ti, Ni, Co, Cu, Nb, Mo, Ru, Pd, Ag, Sn, Mn, La, Hf, Ta, and W.

In this embodiment, similarly to the third embodiment, when a microwave is radiated to the silicon wafer 230 provided with the insulating film 221 that includes the plurality of grooves 251, the surface temperature of the silicon wafer 230 exposed in the bottom of the grooves 251 is higher than the upper surface temperature of the insulating film 221 and the surface temperature of the side wall of the grooves 251 formed from the insulating film 221 by 50° C. or more. When the conductive film 213 is deposited by a CVD method while maintaining the above-described state, the conductive film 213 may be selectively deposited on a place where a surface temperature is high, that is, on the silicon wafer 230, exposed in the bottom of the grooves 251, having a high temperature. Accordingly, since the conductive film 213 is deposited from the bottom of the grooves 251, it is possible to prevent a void from being generated in the conductive film 213 in the grooves 251. Further, it is possible to minimize a thermal damage to a portion other than a place where the conductive film 213 is deposited, and it is possible to suppress a cost of material for the conductive film 213 and a cost of manufacturing.

Furthermore, in this embodiment, similarly to the third embodiment, since a microwave is radiated when the conductive film 213 is deposited by a CVD method, impurities contained in the conductive film 213 may be reduced when compared to a case in which the conductive film 213 is deposited by a CVD method while heating is performed by an RTA method.

Further, according to this embodiment, similarly to the third embodiment, since a temperature of a place where the conductive film 213 is deposited may be higher than a temperature of a portion other than the place, it is possible to avoid a metal element contained in the conductive film 213 being excessively diffused to a portion other than the place where the conductive film 213 is deposited. Furthermore, it is possible to avoid a defect such as a leak being generated in a formed semiconductor device.

### Sixth Embodiment

This embodiment uses a method of manufacturing the interconnections 250 according to the fifth embodiment, and is different from the fifth embodiment in that an air gap 251 is formed between neighboring interconnections 250. For this reason, an insulating film 221 to be used is different from that of the fifth embodiment, and is formed from an organic material film, a polymer material film, or a combination thereof.

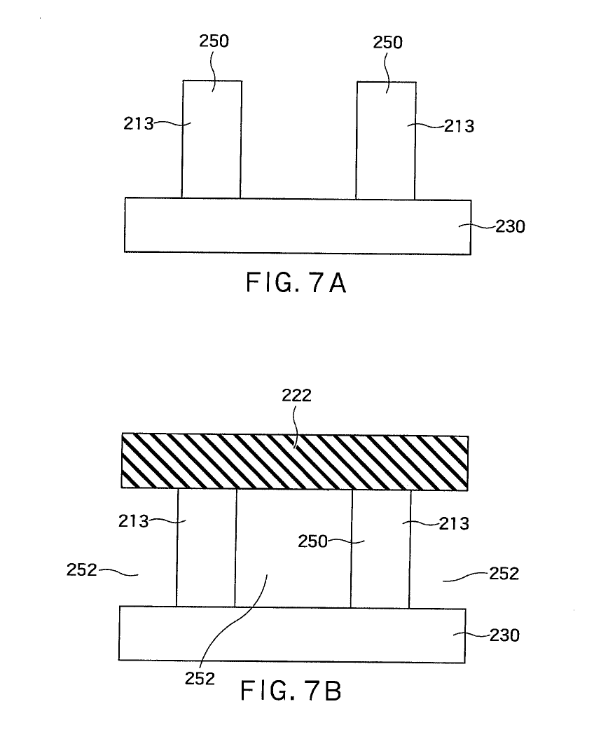

A manufacturing method according to this embodiment will be described with reference to FIGS. 7A and 7B. FIGS. 7A and 7B are cross-sectional views illustrating each process in the manufacturing method according to this embodiment. Here, a process of forming a plurality of interconnections 250 on a silicon wafer 230, and forming an air gap 252 between neighboring interconnections 250 is described as an example. However, the invention is not limited thereto. Further, in description of this embodiment below, the same reference numeral is assigned to a portion having the same configuration and function as that of the embodiments described so far, and description thereof will not be repeated.

First, a method of manufacturing a semiconductor device according to the fifth embodiment illustrated in FIGS. 6A and 6B is performed. In this embodiment, the insulating film (first insulating film) 221 may be formed from an organic material film, a polymer material film, or a combination thereof.

Subsequently, as illustrated in FIG. 7A, the insulating film 221 is removed using an oxygen asher and an oxygen RIE method. Since an increase in temperature of the insulating film 221 is small when a conductive film 213 is deposited, a change in properties of the insulating film 221 such as a film hardening may be avoided, and the insulating film 221 may be easily removed.

Then, as illustrated in FIG. 7B, by forming an insulting film (second insulting film) 222 having a poor coatability on the interconnections 250, the air gap 252 is formed between the interconnections 250.

In this embodiment, since a temperature of a place where the conductive film 213 is deposited is higher than a temperature of a portion other than the place when the conductive film 213 is deposited, an increase in temperature of the insulating film 221 is small, a change in properties of a film such as a film hardening does not occur and thus, the insulating film 221 may be easily removed. Further, since a change in properties due to heat may not be taken into account, a particular material may not be used as the insulating film 221.

Furthermore, in this embodiment, similarly to the fifth embodiment, when a microwave is radiated to the silicon wafer 230 provided with the insulating film 221 that includes a plurality of grooves 251, a surface temperature of the silicon wafer 230 exposed in a bottom of the grooves 251 is higher than an upper surface temperature of the insulating film 221 and a surface temperature of a side wall of the grooves 251 formed from the insulating film 221 by 50° C. or more. When the conductive film 213 is deposited by a CVD method while maintaining the above-described state, the conductive film 213 may be selectively deposited on a place where a surface temperature is high, that is, on the silicon wafer 230, exposed in the bottom of the grooves 251, having a high temperature. Accordingly, since the conductive film 213 is deposited from the bottom of the grooves 251, it is possible to prevent a void from being generated in the conductive film 213 in the grooves 251. Further, it is possible to minimize a thermal damage to a portion other than a place where the conductive film 213 is deposited, and it is possible to suppress a cost of material for the conductive film 213 and a cost of manufacturing.

Furthermore, in this embodiment, similarly to the fifth embodiment, since a microwave is radiated when the conductive film 213 is deposited by a CVD method, impurities contained in the conductive film 213 may be reduced when compared to a case in which the conductive film 213 is deposited by a CVD method while heating is performed by an RTA method and the like.

In addition, according to this embodiment, similarly to the fifth embodiment, since a temperature of a place where the conductive film 213 is deposited is higher than a temperature of a portion other than the place, it is possible to avoid a metal element contained in the conductive film 213 being excessively diffused to a portion other than the place where the conductive film 213 is deposited. Furthermore, it is possible to avoid a defect such as a leak being generated in a formed semiconductor device.

Here, the fifth and sixth embodiments are not limited to the method of forming the interconnections 250 by directly depositing the conductive film 213 in the grooves 251 as illustrated in the foregoing. The conductive film 213 formed from a nickel silicide film and the like may be formed, by forming the conductive film 211 by depositing a silicon film and the like in the grooves 251; and forming the conductive film 212 by selectively depositing a nickel film and the like on the conductive film 211 with radiating a microwave; and performing a heat treatment so that the conductive film 211 reacts with the conductive film 212.

Here, the third to sixth embodiments described so far may be applied to a memory element and the like included in a semiconductor memory device, and may be applied to various places such as an electrode, an interconnection, a contact, and a diffusion layer included in each semiconductor device.

Further, in the third to sixth embodiments described so far, a semiconductor substrate such as the silicon wafer 230 may not be necessarily a silicon substrate, and may be another substrate (for example, a silicon on insulator (SOI) substrate, a SiGe substrate, or the like). In addition, a semiconductor structure and the like may be formed on the various substrates.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor manufacturing apparatus, comprising:
a chamber;
a microwave generator for generating a microwave;
a waveguide for introducing the microwave into the chamber;
a stage for mounting a semiconductor substrate; and
a cover for covering an outer circumference portion of the stage exposed from the semiconductor substrate,
wherein the stage is made of a material to be heated by the microwave, and the cover is made of a material through which the microwave penetrates.

2. The semiconductor manufacturing apparatus according to claim 1, wherein the cover is made of quartz.

3. The semiconductor manufacturing apparatus according to claim 2, wherein the stage is made of a material selected from a polymer material, a magnetic material, and a non-magnetic material having a low resistance.

4. The semiconductor manufacturing apparatus according to claim 1, wherein the stage is made of a material selected from a polymer material, a magnetic material, and a non-magnetic material having a low resistance.

5. The semiconductor manufacturing apparatus according to claim 1, further comprising:
a gas supply system for supplying a gas to the chamber;
a shower plate having a plurality of through-holes, the gas being introduced through the plurality of through-holes; and
a high-frequency power source for generating plasma of the gas,
wherein the microwave is introduced from between the shower plate and the semiconductor substrate.

6. The semiconductor manufacturing apparatus according to claim 5, wherein the shower plate is made of a material selected from a polymer material, a magnetic material, and a non-magnetic material having a low resistance.

7. The semiconductor manufacturing apparatus according to claim 5, wherein an inner diameter of the plurality of through-holes is equal to or less than a half wavelength of the microwave.

8. The semiconductor manufacturing apparatus according to claim 1, further comprising:
a gas supply system for supplying a gas to the chamber;
a target disposed to face the semiconductor substrate in an upper portion inside of the chamber;
a high-frequency power source for generating plasma of the gas; and
a collimator disposed between the target and the semiconductor substrate, and having a plurality of through-holes,
wherein the microwave is introduced into a position between the collimator and the semiconductor substrate.

9. The semiconductor manufacturing apparatus according to claim 8, wherein an inner diameter of the plurality of through-holes is equal to or less than a half wavelength of the microwave.

10. A method of manufacturing a semiconductor device, the method comprising,
radiating a microwave to a semiconductor substrate including a first conductive film and a first insulating film on a surface of the semiconductor substrate to be put a state in which a surface temperature of the first conductive film is higher than a surface temperature of the first insulating film by 50° C. or more, and selectively depositing a second conductive film on the first conductive film using a CVD method.

11. The method of manufacturing a semiconductor device according to claim 10, wherein a metal film, a half metal film, or a metal compound containing at least one element selected from Al, Si, Ti, Ni, Co, Cu, Nb, Mo, Ru, Pd, Ag, Sn, Mn, La, Hf, Ta, and W is used as the second conductive film.

12. The method of manufacturing a semiconductor device according to claim 10, wherein a silicon oxide film, a silicon nitride film, an aluminum oxide film, an aluminum nitride film, a boron nitride film, a silicon oxynitride film, a silicon carbide film, an organic material film, a polymer material film, or a combination film thereof is used as the first insulating film.

13. The method of manufacturing a semiconductor device according to claim 10, further comprising,
performing a heat treatment on the second conductive film after depositing the second conductive film, and forming a third conductive film by causing the first conductive film to react with the second conductive film.

14. A method of manufacturing a semiconductor device, the method comprising:
forming a first insulating film on a semiconductor substrate;
forming a plurality of grooves in the first insulating film to pass through the first insulating film; and
radiating a microwave to the semiconductor substrate including the first insulating film to be put a state in which a surface temperature of exposed parts of the semiconductor substrate is higher than a surface temperature of the first insulating film by 50° C. or more, and selectively depositing a second conductive film on the exposed parts of the semiconductor substrate using a CVD method.

15. The method of manufacturing a semiconductor device according to claim 14, wherein a metal film, a half metal film, or a metal compound containing at least one element selected from Al, Si, Ti, Ni, Co, Cu, Nb, Mo, Ru, Pd, Ag, Sn, Mn, La, Hf, Ta, and W is used as the second conductive film.

16. The method of manufacturing a semiconductor device according to claim 14, wherein a silicon oxide film, a silicon nitride film, an aluminum oxide film, an aluminum nitride film, a boron nitride film, a silicon oxynitride film, a silicon carbide film, an organic material film, a polymer material film, or a combination film thereof is used as the first insulating film.

17. The method of manufacturing a semiconductor device according to claim 14, further comprising:
removing the first insulating film to form an air gap after depositing the second conductive film; and
forming a second insulating film on the second conductive film and the air gap.

18. The method of manufacturing a semiconductor device according to claim 17, wherein an organic material film or a polymer film is used as the first insulating film.
